(19) United States
(12) Patent Application Publication
(10) Pub. No.: US 2017/0075493 A1
(43) Pub. Date: Mar. 16, 2017

(54) CAPACITIVE FORCE SENSING TOUCH PANEL

(71) Applicant: Raydium Semiconductor Corporation, Hsinchu (TW)

(72) Inventors: Kun-Pei LEE, Miaoli County (TW); Chen-Wei Yang, Hsinchu City (TW); Hsin-Wei Shieh, New Taipei City (TW); Yi-Ying Lin, Hualien City, Hualien County (TW); Chang-Ching Chiang, Taichung City (TW)

(21) Appl. No.: 15/242,712

(22) Filed: Aug. 22, 2016

Related U.S. Application Data
(60) Provisional application No. 62/219,491, filed on Sep. 16, 2015.
(60) Provisional application No. 62/248,368, filed on Oct. 30, 2015.

(51) Int. Cl. G06F 3/041; H01L 27/32; G06F 3/044

(52) U.S. Cl. CPC G06F 3/0418; G06F 3/0412; G06F 3/0414; G06F 3/044; H01L 27/323; G06F 2203/04111; G06F 2203/04105

(57) ABSTRACT

A capacitive force sensing touch panel is disclosed. The capacitive force sensing touch panel includes pixels. A laminated structure of each pixel includes a first substrate, an anode layer, an OLED layer, a cathode layer, a second substrate, a first conductive layer and a second conductive layer. The anode layer is disposed above the first substrate. The OLED layer is disposed above the anode layer. The cathode layer is disposed above the OLED layer. The second substrate is disposed above the cathode layer. The first conductive layer and the second conductive layer are disposed on a first plane and a second plane above the OLED layer respectively and selectively driven to be a touch sensing electrode or force sensing electrode.

### BACKGROUND OF THE INVENTION

1. Field of the Invention

This invention relates to touch panel, especially to a capacitive force sensing touch panel.

2. Description of the Prior Art

In general, if capacitive touch electrodes in a capacitive touch panel are also used to be force sensing electrodes at the same time, such as the sensing electrode SE in FIG. 1 is disposed on the upper substrate 12. And, the reference electrode RE can be disposed on the lower substrate 10 in FIG. 1.

When the upper substrate 12 is pressed by a finger, because the distance d between the sensing electrode SE on the upper substrate 12 and the reference electrode RE on the lower substrate 10 will be changed based on different forces provided by the finger, the capacitance sensed between the sensing electrode SE and the reference electrode RE will be also changed accordingly.

However, the capacitive touch sensing signal will be also changed based on different finger pressing areas. When the finger press the touch panel downward, the finger pressing area will be increased and the sensed capacitance will be also changed accordingly. Therefore, the force sensing determined according to capacitance variation will be also affected and no accurate force sensing result can be obtained.

In addition, as shown in FIG. 2A and FIG. 2B, a force sensing module FM can be added into an ordinary touch display apparatus to provide a force sensing function; however, no matter the force sensing module FM is disposed above or under the display panel DP, although force sensing function and touch sensing function can be realized at the same time, the entire thickness of the touch display apparatus will be increased and the costs will be also increased because additional components are necessary to couple the force sensing module FM.

### SUMMARY OF THE INVENTION

Therefore, the invention provides a capacitive force sensing touch panel to solve the above-mentioned problems.

An embodiment of the invention is a capacitive force sensing touch panel. In this embodiment, the capacitive force sensing touch panel includes pixels. A laminated structure of each pixel includes a first substrate, an anode layer, an OLED layer, a cathode layer, a second substrate, a first conductive layer and a second conductive layer. The anode layer is disposed above the first substrate. The OLED layer is disposed above the anode layer. The cathode layer is disposed above the OLED layer. The second substrate is disposed above the cathode layer. The first conductive layer and the second conductive layer are disposed on a first plane and a second plane above the OLED layer respectively and selectively driven to be a touch sensing electrode or force sensing electrode.

In an embodiment, the capacitive force sensing touch panel has an out-cell touch panel structure, an on-cell touch panel structure or an in-cell touch panel structure.

In an embodiment, the first plane and the second plane are two planes of the same substrate or two planes of different substrates respectively, so that the first conductive layer disposed on the first plane and the second conductive layer disposed on the second plane form a mutual-capacitive structure.

In an embodiment, the first plane and the second plane are two planes of the same substrate or two planes of different substrates respectively, so that the first conductive layer disposed on the first plane and the second conductive layer disposed on the second plane form a mutual-capacitive structure.

In an embodiment, the laminated structure further includes an elastic layer disposed between the first plane and the second plane, when the elastic layer is compressed and deformed by force, a distance between the first conductive layer disposed on the first plane and the second conductive layer disposed on the second plane is changed accordingly.

In an embodiment, when the first conductive layer and the second conductive layer are driven to be the touch sensing electrode, the first conductive layer and the second conductive layer include at least one driving electrode and at least one sensing electrode respectively, the at least one driving electrode and the at least one sensing electrode receive a driving signal and a sensing signal respectively.

In an embodiment, when the first conductive layer and the second conductive layer are driven to be the force sensing electrode, the first conductive layer includes at least one driving electrode receiving a force sensing signal, a driving signal or a reference voltage, the second conductive layer includes at least one sensing electrode receiving a ground level or a floating level.

In an embodiment, when the first conductive layer and the second conductive layer are driven to be the touch sensing electrode, the first conductive layer includes at least one driving electrode receiving a driving signal, the second conductive layer includes at least one sensing electrode receiving a sensing signal and at least one dummy electrode receiving a floating level, the at least one sensing electrode and the at least one dummy electrode are spaced from each other.

In an embodiment, when the first conductive layer and the second conductive layer are driven to be the force sensing electrode, the first conductive layer includes at least one driving electrode receiving a force sensing signal, a driving signal or a reference voltage, the second conductive layer includes at least one sensing electrode and at least one dummy electrode, the at least one sensing electrode and the at least one dummy electrode are spaced from each other and both receive a ground level or a floating level.

In an embodiment, the first substrate and the second substrate are formed by a transparent material.

In an embodiment, the laminated structure further includes a cover lens, the cover lens is formed by a transparent material and disposed above the second substrate, the first conductive layer and the second conductive layer.

In an embodiment, the second substrate is formed by an elastic material which can be compressed and deformed by force, the first conductive layer and the second conductive layer are disposed on a lower surface and an upper surface of the second substrate respectively.

In an embodiment, a force sensing mode of the capacitive force sensing touch panel and a display mode of the capacitive force sensing touch panel are driven in a time-sharing way, the capacitive force sensing touch panel is operated in the force sensing mode during a blanking interval of a display period to drive the first conductive layer and the second conductive layer to be the force sensing electrode; the capacitive force sensing touch panel is operated in the display mode and the force sensing mode simultaneously during a display interval of the display period.

In an embodiment, a touch sensing mode and force sensing mode of the capacitive force sensing touch panel and a display mode of the capacitive force sensing touch panel are driven in a time-sharing way, the capacitive force sensing touch panel is operated in the touch sensing mode and the force sensing mode respectively during a blanking interval of a display period to drive the first conductive layer and the second conductive layer to be the touch sensing electrode and the force sensing electrode respectively.

In an embodiment, the blanking interval includes at least one of a vertical blanking interval (VBI), a horizontal blanking interval (HBI), and a long horizontal blanking interval, the long horizontal blanking interval has a time length equal to or larger than that of the horizontal blanking interval, the long horizontal blanking interval is obtained by redistributing a plurality of the horizontal blanking interval or the long horizontal blanking interval includes the vertical blanking interval.

In an embodiment, the second substrate is an encapsulation layer, the second conductive layer is disposed above the first conductive layer, the laminated structure further includes an elastic layer disposed between the cathode layer and the first conductive layer, when the elastic layer is compressed and deformed by force, a distance between the first conductive layer disposed above the elastic layer and the cathode layer disposed under the elastic layer is changed accordingly, but a distance between the first conductive layer and the second conductive layer is not changed.

In an embodiment, the first conductive layer is driven to be force sensing electrodes and the second conductive layer is driven to be touch sensing electrodes.

In an embodiment, when a force is provided to the laminated structure, the second conductive layer is used to shield the first conductive layer.

In an embodiment, the elastic layer is formed by at least one compressible spacer.

In an embodiment, there is a specific proportion between a number of the force sensing electrodes formed by the first conductive layer and a number of the touch sensing electrodes formed by the second conductive layer.

In an embodiment, conducting pads are disposed on the first conductive layer driven to be the force sensing electrodes and the second conductive layer driven to be the touch sensing electrodes respectively and the conducting pads are electrically connected with conduct bars to transmit force sensing signals and touch sensing signals respectively.

In an embodiment, the first conductive layer driven to be the force sensing electrodes is formed by transparent conductive material, and the first conductive layer is divided into blocks partially overlapping a display area of the OLED layer.

In an embodiment, the first conductive layer driven to be the force sensing electrodes is formed by conductive material and disposed above the OLED layer in mesh type without overlapping a display area of the OLED layer.

In an embodiment, the first conductive layer and the second conductive layer are disposed on a lower surface and an upper surface of the second substrate respectively.

In an embodiment, the second conductive layer is disposed on a lower surface of the second substrate and the first conductive layer is disposed between the second conductive layer and the cathode layer.

In an embodiment, when the capacitive force sensing touch panel is operated in a touch sensing mode, the capacitive force sensing touch panel drives the second conductive layer to be touch sensing electrodes and maintains the first conductive layer at a fixed voltage to pretend touch sensing of the touch sensing electrodes from noise interference.

In an embodiment, when the capacitive force sensing touch panel is operated in a force sensing mode, the capacitive force sensing touch panel drives the first conductive layer to be force sensing electrodes and maintains the second conductive layer at a fixed voltage to pretend force sensing of the force sensing electrodes from noise interference and to shield the force sensing electrodes.

In an embodiment, the capacitive force sensing touch panel drives the first conductive layer and the second conductive layer to be force sensing electrodes and touch sensing electrodes respectively with the same amplitude, the same phase or the same frequency to reduce driving loading without decreasing a force sensing time and a touch sensing time.

In an embodiment, a touch sensing period and a display interval of the capacitive force sensing touch panel are at least partially overlapped; during the touch sensing period, the capacitive force sensing touch panel drives the second conductive layer to be touch sensing electrodes and maintains the first conductive layer at a fixed voltage.

In an embodiment, a force sensing period and a display interval of the capacitive force sensing touch panel are at least partially overlapped.

Another embodiment of the invention is also a capacitive force sensing touch panel. In this embodiment, the capacitive force sensing touch panel includes pixels. A laminated structure of each pixel includes a first substrate, an anode layer, an OLED layer, a cathode layer, a second substrate and a conductive layer. The anode layer is disposed above the first substrate. The OLED layer is disposed above the anode layer. The cathode layer is disposed above the OLED layer. The second substrate is disposed above the cathode layer. The conductive layer is disposed under the OLED layer to be a force sensing electrode.

Compared to the prior art, the capacitive force sensing touch panel of the invention has the following advantages and effects:

(1) During the force sensing period, a relative upper electrode is used to avoid the effects caused by the change of the finger pressing area to maintain the accurate sensed capacitance.

(2) Touch sensing and force sensing of the capacitive force sensing touch panel can be driven in a time-sharing way and operated during the blanking interval of the display period to avoid the noise interference of the liquid crystal module.

(3) If the sensing electrode is disposed above the OLED layer, it can be switched to do touch sensing or force sensing by a touch signal; therefore, additional force sensing electrode disposed in the capacitive force sensing touch panel will be unnecessary. If the sensing electrode is disposed under the OLED layer, it can have better timing and material options.

(4) The capacitive force sensing touch panel of the invention can be applied to different touch panel structures such as in-cell touch panel structure, on-cell touch panel structure or out-cell touch panel structure.

(5) The capacitive force sensing touch panel of the invention can provide the force sensing function and the touch sensing function at the same time without increasing the original entire thickness of the touch display apparatus.

The advantage and spirit of the invention may be understood by the following detailed descriptions together with the appended drawings.

### BRIEF DESCRIPTION OF THE APPENDED DRAWINGS

FIG. 1 illustrates a schematic diagram of the capacitive touch sensing electrode in conventional capacitive touch panel also used as the force sensing electrode.

FIG. 2A and FIG. 2B illustrate schematic diagrams of adding a force sensing module into an ordinary touch display apparatus.

FIG. 3 illustrates a schematic diagram of the laminated structure of the pixel of the OLED display panel.

FIG. 4A˜FIG. 4C illustrate schematic diagrams of the first conductive layer and the second conductive layer disposed on different planes above the OLED layer respectively in an embodiment of the invention.

FIG. 5A˜FIG. 5C illustrate schematic diagrams of the first conductive layer and the second conductive layer disposed on different planes above the OLED layer respectively in another embodiment of the invention.

FIG. 6A˜FIG. 6C illustrate the first conductive layer and the second conductive layer disposed in the laminated structure of the capacitive force sensing touch panel in different embodiments.

FIG. 7A illustrates a timing diagram of the force sensing mode and the display mode of the capacitive force sensing touch panel driven in a time-sharing way.

FIG. 7B illustrates a timing diagram of the touch sensing mode and the force sensing mode of the capacitive force sensing touch panel driven in a time-sharing way.

FIG. 7C illustrates a schematic diagram of the blanking interval including a vertical blanking interval (VBI), a horizontal blanking interval (HBI) and a long horizontal blanking interval.

FIG. 8A and FIG. 8B illustrate different embodiments of the conductive layer disposed under the OLED layer.

FIG. 9A illustrates a schematic diagram of the touch sensing electrode disposed on the encapsulation layer and the force sensing electrode disposed under the touch sensing electrode in the laminated structure of the on-cell touch panel.

FIG. 9B illustrates a schematic diagram of the touch sensing electrode disposed out of the encapsulation layer and the force sensing electrode disposed under the touch sensing electrode in the laminated structure of the out-cell touch panel.

FIG. 9C illustrates a schematic diagram of the touch sensing electrode disposed within the encapsulation layer and the force sensing electrode disposed under the touch sensing electrode in the laminated structure of the in-cell touch panel.

FIG. 10A and FIG. 10B illustrate schematic diagrams of the capacitive force sensing touch panel when it is not pressed and when it is pressed respectively.

FIG. 11A illustrates an embodiment of the layout of the force sensing electrode and the touch sensing electrode.

FIG. 11B and FIG. 11C illustrate schematic diagrams of the first conductive layer disposed above the OLED layer in block type or mesh type respectively.

FIG. 12A illustrates another embodiment of the laminated structure of the capacitive force sensing touch panel.

FIG. 12B illustrates another embodiment of the layout of the force sensing electrode and the touch sensing electrode.

FIG. 13A˜FIG. 13D illustrate timing diagrams of the touch sensing driving and force sensing driving of the capacitive force sensing touch panel in different embodiments respectively.

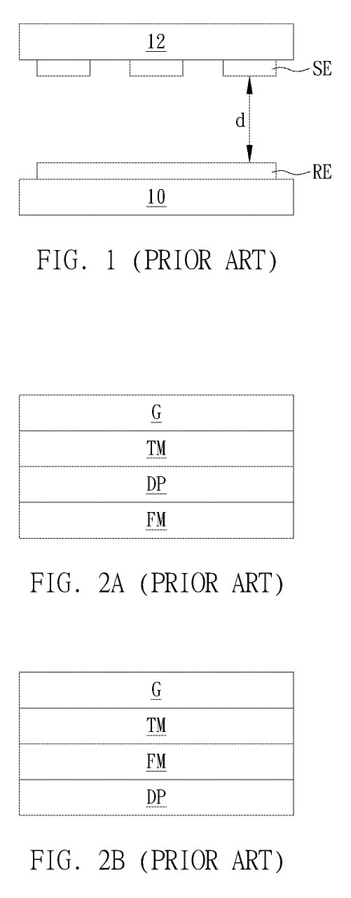

### DETAILED DESCRIPTION OF THE INVENTION

A preferred embodiment of the invention is a capacitive force sensing touch panel. In this embodiment, the capacitive force sensing touch panel can have different touch panel structures such as in-cell touch panel structure, on-cell touch panel structure or out-cell touch panel structure, and the capacitive force sensing touch panel can be an OLED display panel, but not limited to this.

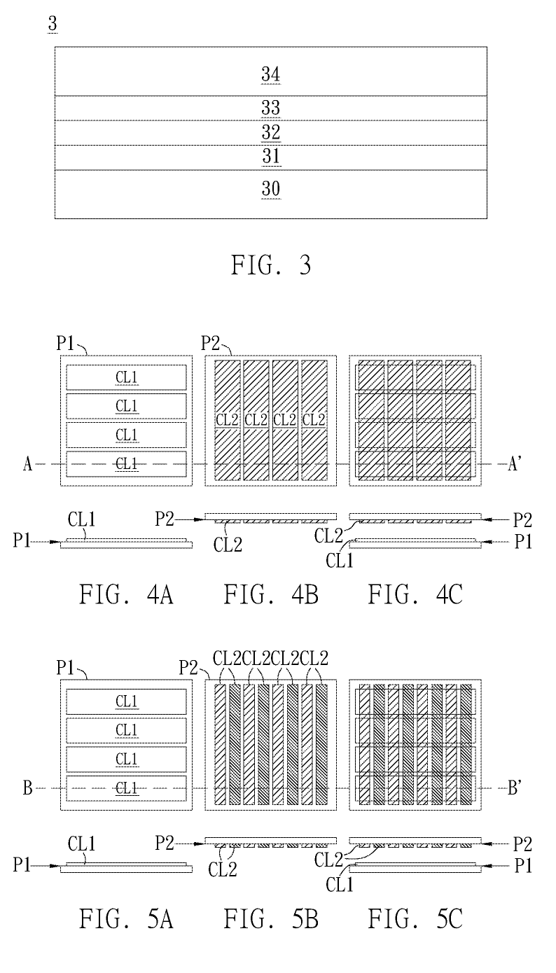

Please refer to FIG. 3. FIG. 3 illustrates a schematic diagram of the laminated structure of the pixel of the OLED display panel. AS shown in FIG. 3, the laminated structure 3 includes a first substrate 30, an anode layer 31, an OLED layer 32, a cathode layer 33 and a second substrate 34. Wherein, the anode layer 31 is disposed between the first substrate 30 and the OLED layer 32; the cathode layer 33 is disposed between the OLED layer 32 and the second substrate 34.

It should be noticed that, in the laminated structure of the pixel of the capacitive force sensing touch panel of the invention, a first conductive layer and a second conductive layer can be disposed on different planes above the OLED layer respectively and the first conductive layer and the second conductive layer can be driven to be touch sensing electrodes or force sensing electrodes in different timings.

Please refer to FIG. 4A˜FIG. 4C. FIG. 4A˜FIG. 4C illustrate schematic diagrams of the first conductive layer and the second conductive layer disposed on different planes above the OLED layer respectively in an embodiment of the invention. As shown in FIG. 4A˜FIG. 4C, the first plane P1 and the second plane P2 are both disposed above the OLED layer, and the second plane P2 is disposed above the first plane P1. That is to say, the first plane P1 will be closer to the OLED layer than the second plane P2. And, the first conductive layer CL1 and the second conductive layer CL2 are disposed on the first plane P1 and the second plane P2 respectively. In fact, there can be an elastic layer disposed between the first plane P1 and the second plane P2. When the elastic layer is compressed and deformed by force, a distance between the first conductive layer CL1 disposed on the first plane P1 and the second conductive layer CL2 disposed on the second plane P2 will be changed accordingly, but not limited to this.

It should be noticed that the first plane P1 and the second plane P2 mentioned above can be two planes of the same substrate or two planes of different substrates respectively, so that the first conductive layer CL1 disposed on the first plane P1 and the second conductive layer CL2 disposed on the second plane P2 can form a mutual-capacitive sensing structure.

The first conductive layer CL1 and the second conductive layer CL2 can be selectively driven to be touch sensing electrodes or force sensing electrodes. In an embodiment, when the first conductive layer CL1 and the second conductive layer CL2 are driven to be the touch sensing electrodes during the touch sensing period, the first conductive layer CL1 and the second conductive layer CL2 will include at least one driving electrode (TX) and at least one sensing electrode (RX) respectively and receive a driving signal and a sensing signal respectively to finish capacitive touch sensing; when the first conductive layer CL1 and the second conductive layer CL2 are driven to be the force sensing electrodes during the force sensing period, the first conductive layer CL1 will include at least one driving electrode (TX) receiving a force sensing signal, a driving signal or a reference voltage and the second conductive layer CL2 will include at least one sensing electrode (RX) receiving a ground level or a floating level, but not limited to this.

In another embodiment, as shown in FIG. 5A˜FIG. 5C, when the first conductive layer CL1 and the second conductive layer CL2 are driven to be the touch sensing electrodes during the touch sensing period, the first conductive layer CL1 will include at least one driving electrode (TX) receiving a driving signal and the second conductive layer CL2 will include at least one sensing electrode (RX) receiving a sensing signal and at least one dummy electrode (DE) receiving a floating level, wherein the at least one sensing electrode (RX) and the at least one dummy electrode (DE) are spaced from each other; when the first conductive layer CL1 and the second conductive layer CL2 are driven to be the force sensing electrodes during the force sensing period, the first conductive layer CL1 will include at least one driving electrode (TX) receiving a force sensing signal, a driving signal or a reference voltage and the second conductive layer CL2 will include at least one sensing electrode (RX) and at least one dummy electrode (DE) both receiving a ground level or a floating level, wherein the at least one sensing electrode (RX) and the at least one dummy electrode (DE) are spaced from each other, but not limited to this.

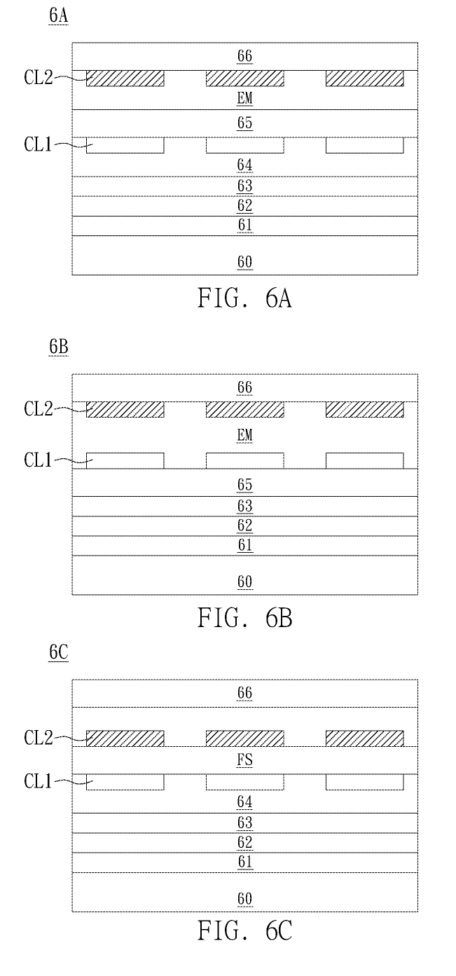

Then, please refer to FIG. 6A˜FIG. 6C. FIG. 6A˜FIG. 6C illustrate the first conductive layer CL1 and the second conductive layer CL2 disposed in the laminated structure of the capacitive force sensing touch panel in different embodiments.

In fact, the first substrate 60 and the second substrate 65 are formed by transparent material (e.g., glass material or elastic material). The cover lens 66 formed by transparent material (e.g., glass material or elastic material) is disposed above the second substrate 65, the first conductive layer CL1 and the second conductive layer CL2. At least one elastic layer is disposed between the first conductive layer CL1 and the second conductive layer CL2, such as the elastic material layer shown in FIG. 6A and FIG. 6B or the flexible substrate FS shown in FIG. 6C, but not limited to this. An adhesive layer can be disposed between the substrates or between the substrate and the cover lens, but not limited to this.

In FIG. 6A, the first conductive layer CL1 is disposed on the lower surface of the second substrate 65 and the second conductive layer CL2 is disposed on the lower surface of the cover lens 66. When the cover lens 66 is pressed, the elastic material layer EM disposed between the first conductive layer CL1 and the second conductive layer CL2 will be pressed and deformed by force and the distance between the first conductive layer CL1 and the second conductive layer CL2 will be changed to generate the variation of sensed capacitance.

In FIG. 6B, the first conductive layer CL1 is disposed on the upper surface of the second substrate 65 and the second conductive layer CL2 is disposed on the lower surface of the cover lens 66. When the cover lens 66 is pressed, the elastic material layer EM disposed between the first conductive layer CL1 and the second conductive layer CL2 will be pressed and deformed by force and the distance between the first conductive layer CL1 and the second conductive layer CL2 will be changed to generate the variation of sensed capacitance.

In FIG. 6C, the first conductive layer CL1 and the second conductive layer CL2 are disposed on the lower surface and the upper surface of the flexible substrate FS respectively. When the cover lens 66 is pressed, the flexible substrate FS disposed between the first conductive layer CL1 and the second conductive layer CL2 will be pressed and deformed by force and the distance between the first conductive layer CL1 and the second conductive layer CL2 will be changed to generate the variation of sensed capacitance.

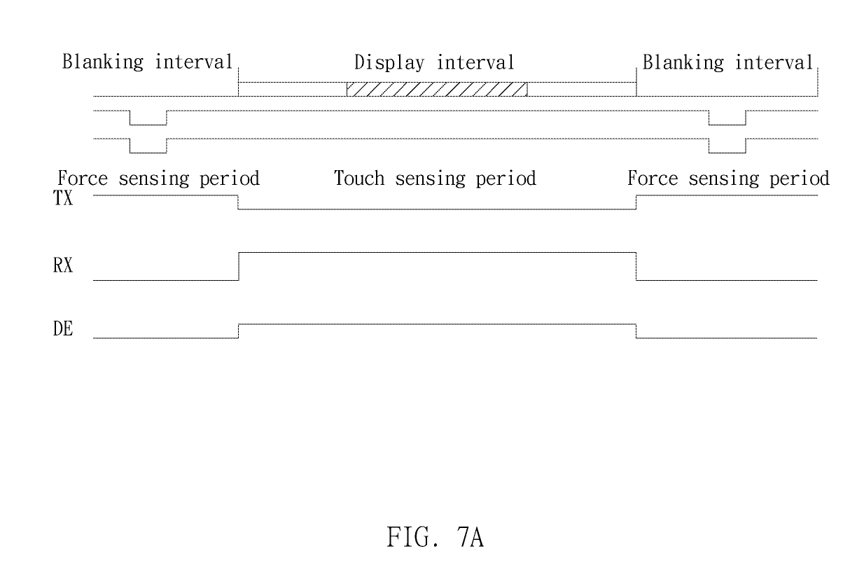

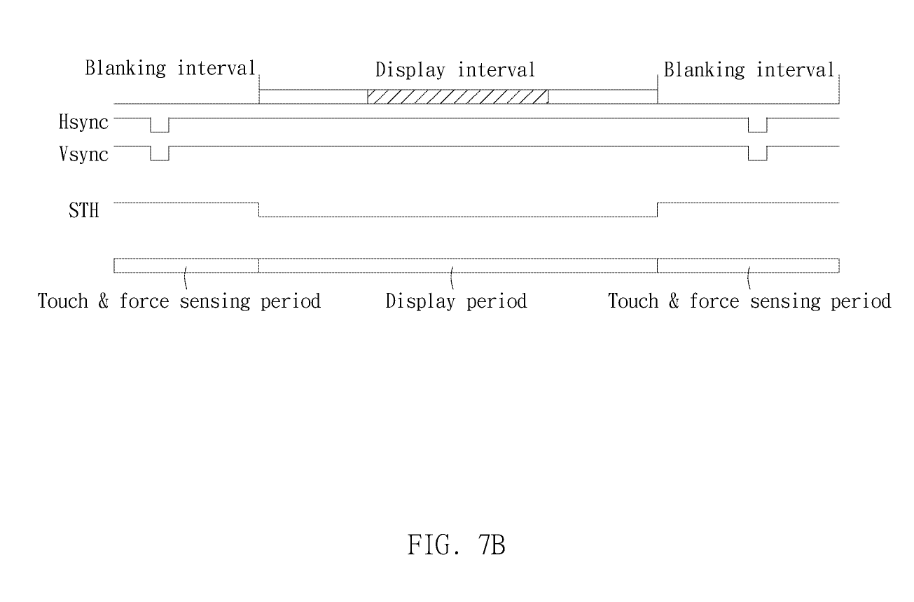

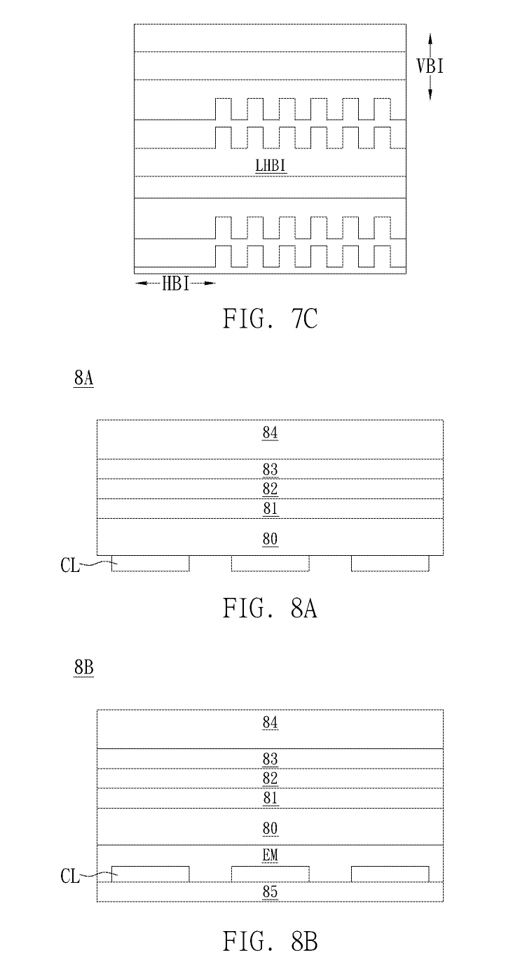

In an embodiment, the force sensing mode and the display mode of the capacitive force sensing touch panel are driven in a time-sharing way. As shown in FIG. 7A, the capacitive force sensing touch panel is operated in the force sensing mode during a blanking interval of the display period and the capacitive force sensing touch panel drives the first conductive layer and the second conductive layer to be force sensing electrodes. The capacitive force sensing touch panel is operated in the display mode and the touch sensing mode simultaneously during a display interval of the display period, but not limited to this.

In another embodiment, the touch sensing mode and the force sensing mode of the capacitive force sensing touch panel and the display mode of the capacitive force sensing touch panel are driven in a time-sharing way. As shown in FIG. 7B, the capacitive force sensing touch panel is operated in the touch sensing mode and the force sensing mode respectively during a blanking interval of the display period and the capacitive force sensing touch panel drives the first conductive layer and the second conductive layer to be touch sensing electrodes and force sensing electrodes respectively, but not limited to this.

In practical applications, as shown in FIG. 7C, the blanking interval includes at least one of a vertical blanking interval (VBI), a horizontal blanking interval (HBI), and a long horizontal blanking interval (LHBI). The long horizontal blanking interval LHBI has a time length equal to or larger than that of the horizontal blanking interval HBI; the long horizontal blanking interval LHBI is obtained by redistributing a plurality of the horizontal blanking interval HBI or the long horizontal blanking interval LHBI includes the vertical blanking interval VBI, but not limited to this.

It should be noticed that not only the above-mentioned embodiments that the conductive layer forming sensing electrodes is disposed above the OLED layer, the conductive layer forming sensing electrodes of the invention can be also disposed under the OLED layer driven to be force sensing electrodes.

As shown in FIG. 8A, the conductive layer CL is disposed under the OLED layer 82 and disposed on the lower surface of the first substrate 80. At least one elastic layer or air is disposed between the conductive layer CL and the cathode layer 83. When a pressing force is provided, the conductive layer CL can sense the capacitance variation through the change of the distance between the conductive layer CL and the cathode layer 83. In fact, the force sensing mode of the capacitive force sensing touch panel and the touch sensing mode and the display mode of the capacitive force sensing touch panel can be operated in a time-sharing way or simultaneously. The force sensing electrodes formed by the conductive layer CL can be single-layer self-capacitive design or single-layer mutual-capacitive design. The conductive layer CL can be formed by transparent conductive material or opaque conductive material, but not limited to this.

As shown in FIG. 8B, the conductive layer CL is disposed under the OLED layer 82 and disposed on the lower surface of the first substrate 80; the third substrate 85 is disposed under the conductive layer CL. The elastic material layer EM is disposed between the conductive layer CL and the cathode layer 83. When a pressing force is provided, the conductive layer CL can sense the capacitance variation through the change of the distance between the conductive layer CL and the cathode layer 83. In addition, the shielding electrode can be disposed above the conductive layer CL. When the conductive layer CL is driven to be force sensing electrodes, the shielding electrode can be reference electrode or ground electrode, but not limited to this.

In fact, the force sensing mode of the capacitive force sensing touch panel and the touch sensing mode and the display mode of the capacitive force sensing touch panel can be operated in a time-sharing way or simultaneously. The force sensing electrodes formed by the conductive layer CL can be single-layer self-capacitive design or single-layer mutual-capacitive design. The conductive layer CL can be formed by transparent conductive material or opaque conductive material, but not limited to this.

Another preferred embodiment of the invention is also a capacitive force sensing touch panel. In this embodiment, the capacitive force sensing touch panel can have different touch panel structures such as in-cell touch panel structure, on-cell touch panel structure or out-cell touch panel structure, and the capacitive force sensing touch panel can be an OLED display panel, but not limited to this.

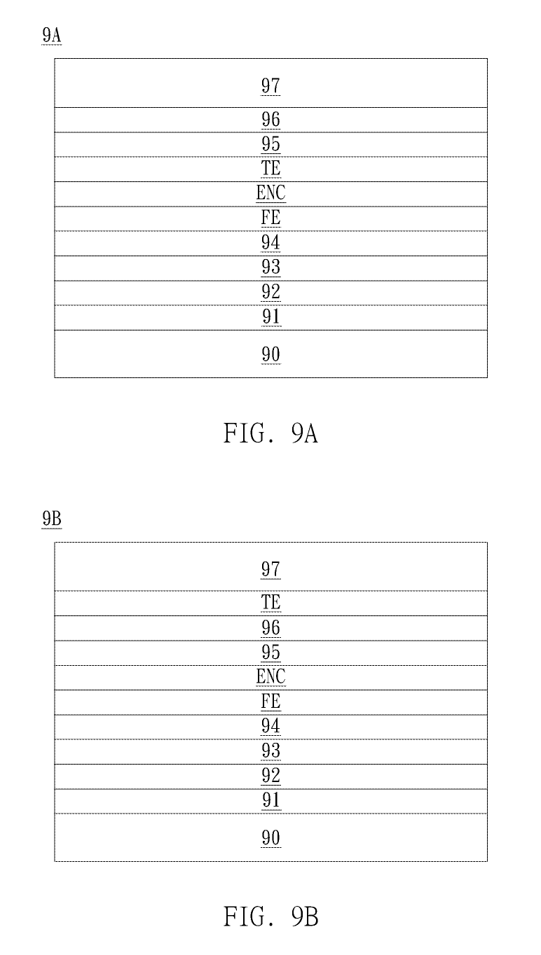

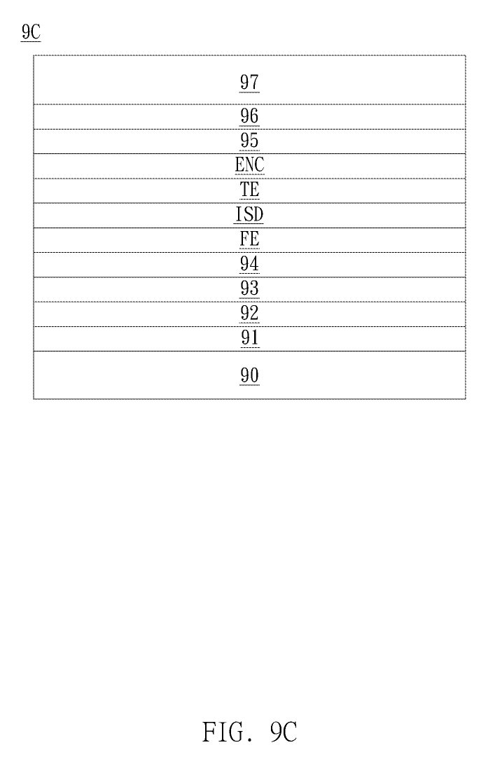

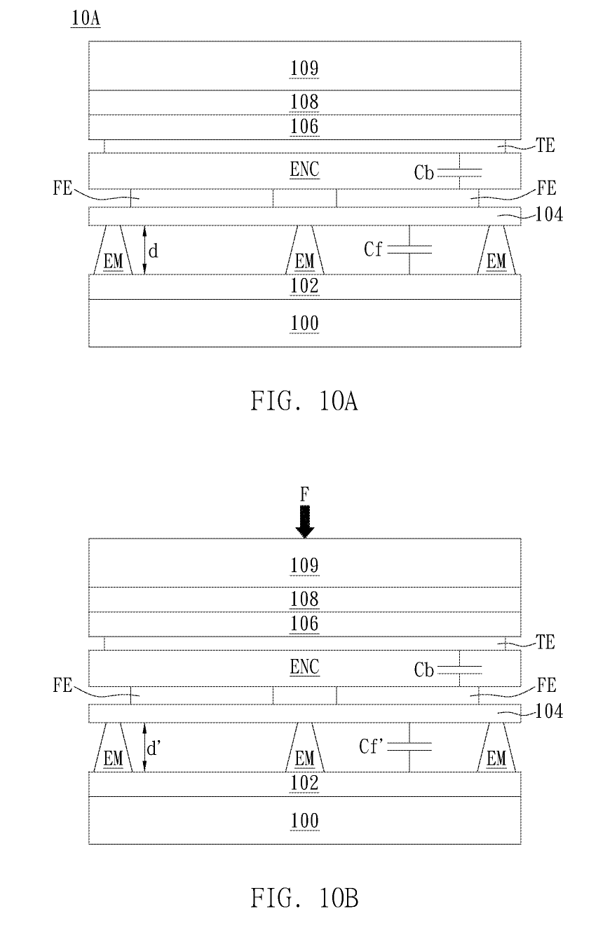

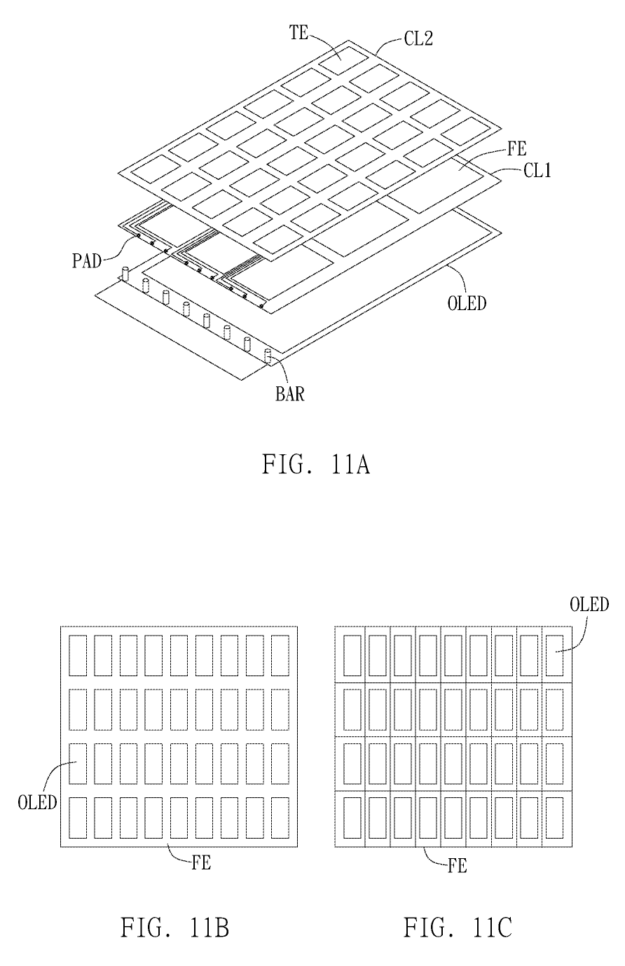

For example, FIG. 9A shows that the touch sensing electrode TE is disposed on the encapsulation layer ENC and the force sensing electrode FE is disposed under the touch sensing electrode TE in the laminated structure 9A of the on-cell touch panel; FIG. 9B shows that the touch sensing electrode TE is disposed out of the encapsulation layer ENC and the force sensing electrode FE is disposed under the touch sensing electrode TE in the laminated structure 9B of the out-cell touch panel; FIG. 9C shows that the touch sensing electrode TE is disposed within the encapsulation layer ENC and the force sensing electrode FE is disposed under the touch sensing electrode TE in the laminated structure 9C of the in-cell touch panel.

It should be noticed that the force sensing electrode FE in this embodiment combines the laminated structure of the touch panel to achieve slim design. When the force sensing electrode FE is operated, the touch sensing electrode TE which is disposed above the force sensing electrode FE can shield the force sensing electrode FE, so that the force sensing electrode FE will not affected by the variation of finger pressing area and the sensed capacitance will be accurate.

In addition, the reference electrode coupled to reference voltage or ground is disposed under the force sensing electrode FE. When the touch panel is pressed by finger, the distance between the force sensing electrode FE and the reference electrode will be changed and the sensed capacitance will be also changed accordingly. In fact, the reference electrode can be the anode 91 or cathode 93 in FIG. 9A˜FIG. 9C, but not limited to this.

Taking the capacitive force sensing touch panel having the on-cell laminated structure for example, as shown in FIG. 10A, the touch sensing electrode TE is disposed on the upper surface of the encapsulation layer ENC and the force sensing electrode FE is disposed on the lower surface of the encapsulation layer ENC, and the cathode layer 102 is disposed under the force sensing electrode FE. At least one elastic layer EM is disposed between the force sensing electrode FE and the cathode layer 102.

FIG. 10A and FIG. 10B illustrate schematic diagrams of the capacitive force sensing touch panel when it is not pressed and when it is pressed respectively. As shown in FIG. 10A, when the capacitive force sensing touch panel 10A is not pressed, if the capacitance between the touch sensing electrode TE and the force sensing electrode FE is Cb, the capacitance between the force sensing electrode FE and the cathode layer 102 is Cf, and the distance between the touch sensing electrode TE and the force sensing electrode FE is d; when the capacitive force sensing touch panel is pressed by a force F, since the height of the encapsulation layer ENC is not changed, the capacitance between the touch sensing electrode TE and the force sensing electrode FE still maintains Cb, but the elastic layer EM will be pressed by the force F and the height of the elastic layer EM will be changed from d to d′, so that the capacitance between the force sensing electrode FE and the cathode layer 102 will be changed from Cf to Cf′; therefore, there will be a capacitance variation generated. In fact, the elastic layer EM can be formed by at least one compressed spacer, but not limited to this.

Although the capacitive force sensing touch panel having the on-cell laminated structure is taken for example above, but the touch sensing electrode TE is not limited to be disposed on the upper surface of the encapsulation layer ENC. In fact, the touch sensing electrode TE can be also disposed out of the encapsulation layer ENC to form the out-cell laminated structure or the touch sensing electrode TE can be also disposed within the encapsulation layer ENC to form the in-cell laminated structure. The only requirement is that the touch sensing electrode TE can effectively shield the mutual electrical field between the force sensing electrode FE and the object (e.g., finger) proving pressure from outside.

Then, please refer to FIG. 11A. FIG. 11A illustrates an embodiment of the layout of the force sensing electrode and the touch sensing electrode. As shown in FIG. 11A, there is a specific proportion between a number of the force sensing electrodes FE formed by the first conductive layer CL1 and a number of the touch sensing electrodes TE formed by the second conductive layer CL2; for example, the proportion of 9:30 shown in FIG. 11A, that is to say, 30 touch sensing electrodes TE disposed on the upper second conductive layer CL2 are used to shield 9 force sensing electrodes FE disposed on the lower first conductive layer CL1, but not limited to this. In addition, conducting pads PAD are disposed on the first conductive layer CL1 driven to be the force sensing electrodes FE and the conducting pads PAD can be electrically connected with conduct bars BAR disposed beside the OLED layer to transmit force sensing signals and touch sensing signals respectively, but not limited to this.

In an embodiment, as shown in FIG. 11B, the first conductive layer CL1 driven to be the force sensing electrodes FE is formed by transparent conductive material and partially overlaps the display area of the OLED layer in block type.

In another embodiment, as shown in FIG. 11C, the first conductive layer CL1 driven to be the force sensing electrodes FE is formed by conductive material and disposed above the OLED layer in mesh type without overlapping the display area of the OLED layer to reduce the effects of the force sensing electrodes FE on the light-emitting efficiency of the display apparatus.

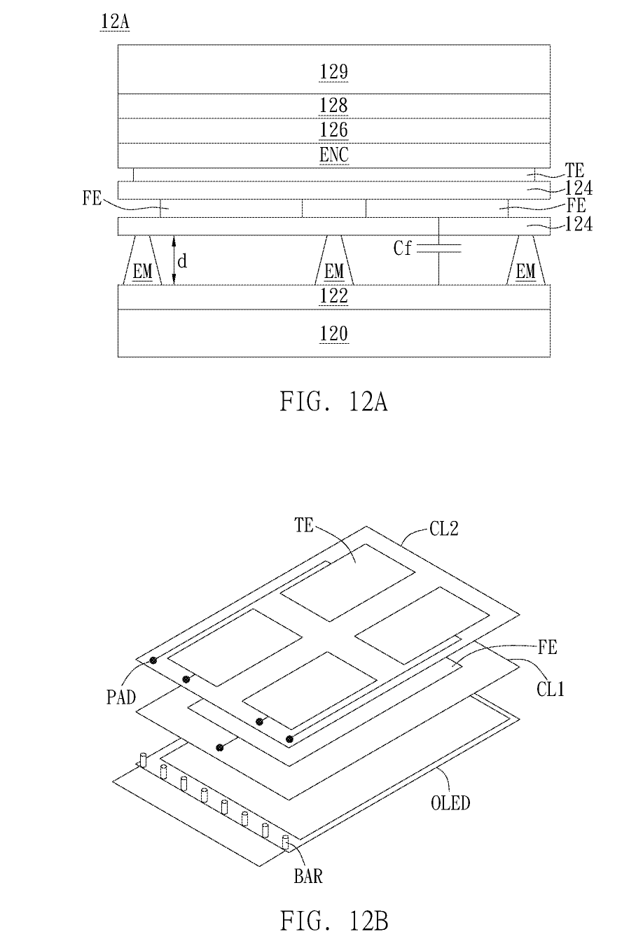

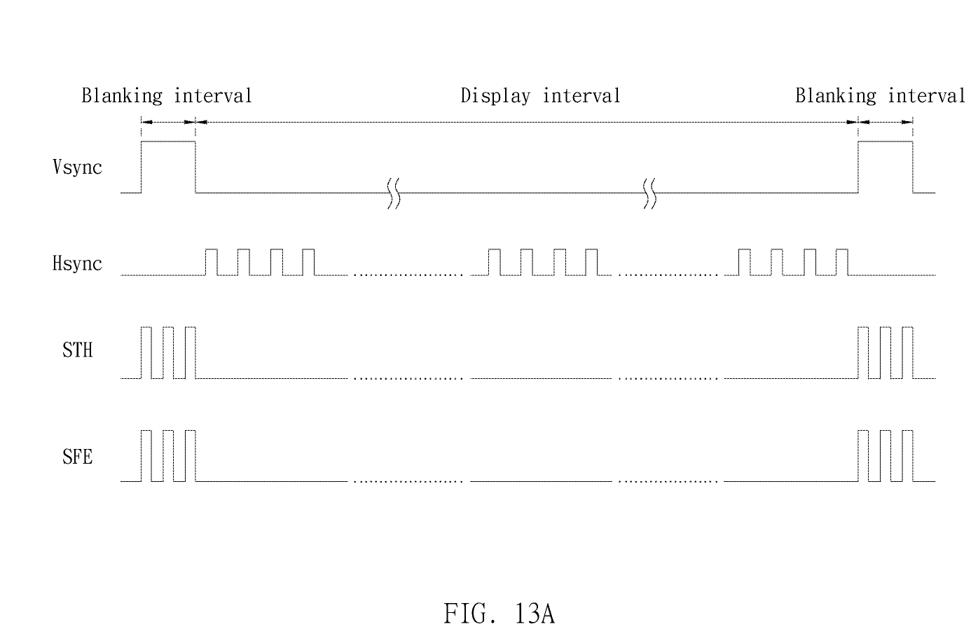

Taking the laminated structure 12A of the in-cell capacitive force sensing touch panel for example, as shown in FIG. 12A, the touch sensing electrode TE is disposed on the lower surface of the encapsulation layer ENC and the force sensing electrode FE is disposed under the touch sensing electrode TE, the cathode layer 122 is disposed under the force sensing electrode FE and at least one elastic layer EM is disposed between the force sensing electrode FE and the cathode layer 122.

When the capacitive force sensing touch panel is pressed by a force, the elastic layer EM is compressed by the force and its height will be changed from d to d′ and the capacitance between the force sensing electrode FE and the cathode layer 122 will be also changed from Cf to Cf′; therefore, there will be a capacitance variation generated. In fact, the elastic layer EM can be formed by at least one compressed spacer, but not limited to this.

As shown in FIG. 12B, there is a specific proportion between a number of the force sensing electrodes FE formed by the first conductive layer CL1 and a number of the touch sensing electrodes TE formed by the second conductive layer CL2; for example, the proportion of 1:4 shown in FIG. 12B, that is to say, the upper four touch sensing electrodes TE are used to shield the lower one force sensing electrode FE, but not limited to this. In addition, conducting pads PAD are disposed on the first conductive layer CL1 driven to be the force sensing electrodes FE and the second conductive layer CL2 driven to be the touch sensing electrodes TE respectively and the conducting pads PAD can be electrically connected with conduct bars BAR to transmit force sensing signals and touch sensing signals respectively, but not limited to this.

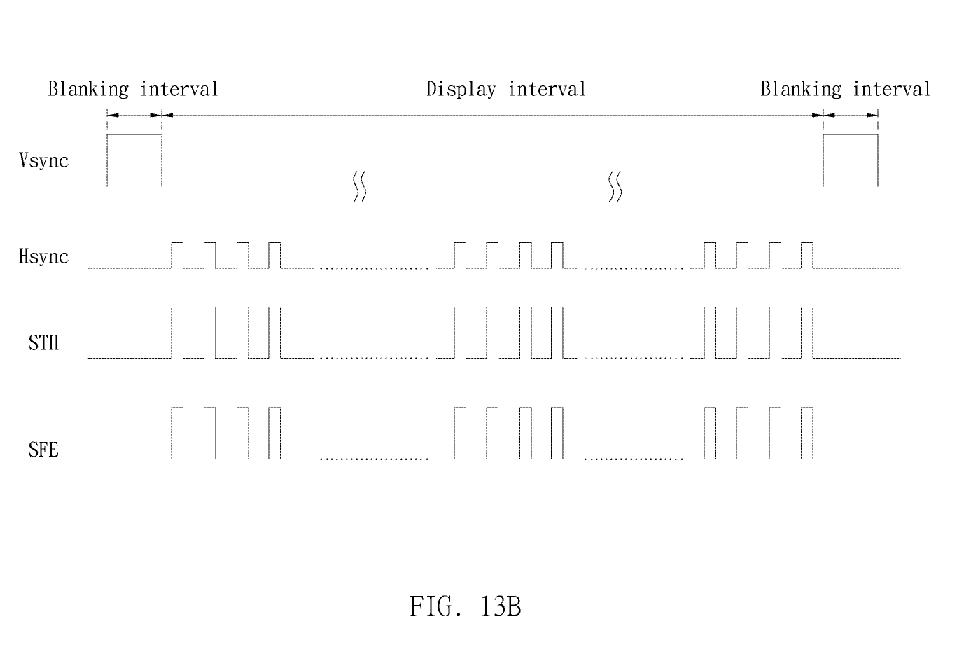

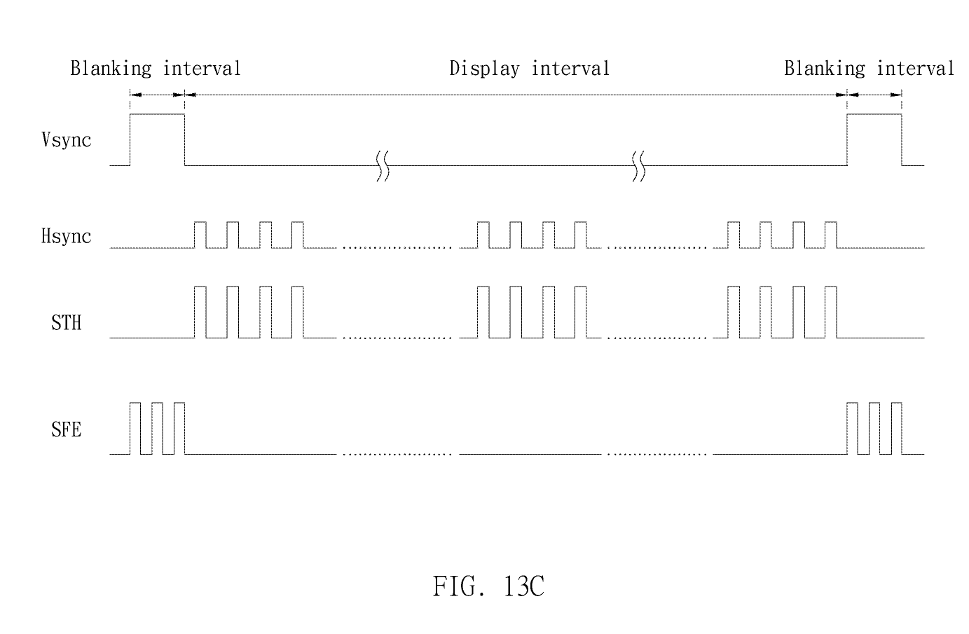

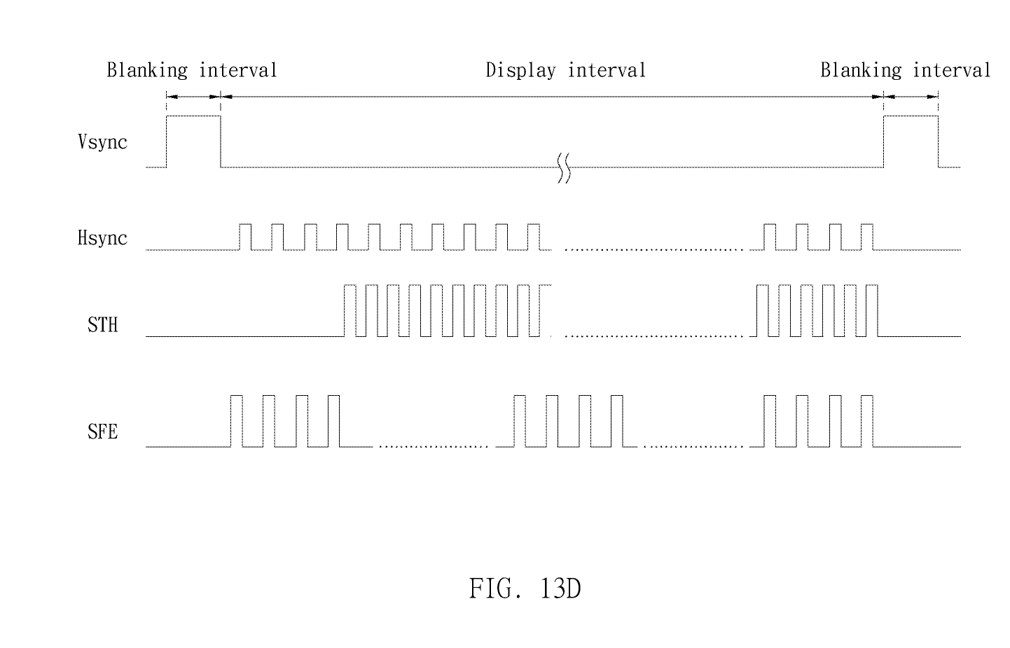

As stated above, the touch sensing and the force sensing of the capacitive force sensing touch panel of the invention can be operated during the blanking interval of the display period. For example, as shown in FIG. 13A, the touch sensing driving signal STH and the force sensing driving signal SFE are both operated during the blanking interval of the vertical synchronous signal Vsync; as shown in FIG. 13C, the force sensing driving signal SFE is operated during the blanking interval of the vertical synchronous signal Vsync, but the touch sensing driving signal STH is not.

As shown in FIG. 7C, the blanking interval includes at least one of a vertical blanking interval VBI, a horizontal blanking interval HBI, and a long horizontal blanking interval LHBI. The long horizontal blanking interval LHBI has a time length equal to or larger than that of the horizontal blanking interval HBI; the long horizontal blanking interval LHBI is obtained by redistributing a plurality of the horizontal blanking interval HBI or the long horizontal blanking interval LHBI includes the vertical blanking interval VBI, but not limited to this. In fact, when the touch sensing and the force sensing of the capacitive force sensing touch panel of the invention are operated during the blanking interval of the display period, they can be adjusted based on different driving ways to use more than one kind of blanking interval; for example, the long horizontal blanking interval LHBI and vertical blanking interval VBI, but not limited to this.

In fact, if considering the factor of noise, the touch sensing and the force sensing of the capacitive force sensing touch panel of the invention can be operated independently without synchronizing with the vertical synchronous signal Vsync or horizontal synchronous signal Hsync, but not limited to this.

In an embodiment, when the capacitive force sensing touch panel is operated in the touch sensing mode, the capacitive force sensing touch panel will drive the second conductive layer to be touch sensing electrodes TE and maintain the first conductive layer at a fixed voltage (e.g., ground voltage) to avoid the noise interfering the touch sensing of the touch sensing electrodes TE, but not limited to this; when the capacitive force sensing touch panel is operated in the force sensing mode, the capacitive force sensing touch panel will drive the first conductive layer to be force sensing electrodes FE and maintain the second conductive layer at a fixed voltage (e.g., ground voltage) to avoid the noise interfering the force sensing of the force sensing electrodes FE, but not limited to this.

In another embodiment, the capacitive force sensing touch panel of the invention can drive the first conductive layer and the second conductive layer to be force sensing electrodes FE and touch sensing electrodes TE respectively with the same amplitude, the same phase or the same frequency to reduce driving loading without decreasing a force sensing time and a touch sensing time. For example, as shown in FIG. 13A, the touch sensing driving signal STH and the force sensing driving signal SFE are both operated during the blanking interval of the vertical synchronous signal Vsync and they both have the same amplitude, the same phase and the same frequency; as shown in FIG. 13B, the touch sensing driving signal STH and the force sensing driving signal SFE are both synchronous with the vertical synchronous signal Vsync and they both have the same amplitude, the same phase and the same frequency.

In fact, the touch sensing period of the capacitive force sensing touch panel can at least partially overlap the display period, as shown in FIG. 13B˜FIG. 13D. In addition, the force sensing period of the capacitive force sensing touch panel can at least partially overlap the display period, as shown in FIG. 13B and FIG. 13D.

Compared to the prior art, the capacitive force sensing touch panel of the invention has the following advantages and effects:

(1) During the force sensing period, a relative upper electrode is used to avoid the effects caused by the change of the finger pressing area to maintain the accurate sensed capacitance.

(2) Touch sensing and force sensing of the capacitive force sensing touch panel can be driven in a time-sharing way and operated during the blanking interval of the display period to avoid the noise interference of the liquid crystal module.

(3) If the sensing electrode is disposed above the OLED layer, it can be switched to do touch sensing or force sensing by a touch signal; therefore, additional force sensing electrode disposed in the capacitive force sensing touch panel will be unnecessary. If the sensing electrode is disposed under the OLED layer, it can have better timing and material options.

(4) The capacitive force sensing touch panel of the invention can be applied to different touch panel structures such as in-cell touch panel structure, on-cell touch panel structure or out-cell touch panel structure.

(5) The capacitive force sensing touch panel of the invention can provide the force sensing function and the touch sensing function at the same time without increasing the original entire thickness of the touch display apparatus.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A capacitive force sensing touch panel, comprising:
a plurality of pixels, a laminated structure of each pixel comprising:
a first substrate;
an anode layer disposed above the first substrate;
an organic light-emitting diode (OLED) layer disposed above the anode layer;
a cathode layer disposed above the OLED layer;
a second substrate disposed above the cathode layer; and
a first conductive layer and a second conductive layer disposed on a first plane and a second plane above the OLED layer respectively and selectively driven to be a touch sensing electrode or a force sensing electrode.

2. The capacitive force sensing touch panel of claim 1, wherein the capacitive force sensing touch panel has an out-cell touch panel structure, an on-cell touch panel structure or an in-cell touch panel structure.

3. The capacitive force sensing touch panel of claim 1, wherein the first plane and the second plane are two planes of the same substrate or two planes of different substrates respectively, so that the first conductive layer disposed on the first plane and the second conductive layer disposed on the second plane form a mutual-capacitive structure.

4. The capacitive force sensing touch panel of claim 1, wherein the first plane is disposed under the second plane, the first plane is closer to the OLED layer than the second plane.

5. The capacitive force sensing touch panel of claim 1, wherein the laminated structure further comprises an elastic layer disposed between the first plane and the second plane, when the elastic layer is compressed and deformed by force, a distance between the first conductive layer disposed on the first plane and the second conductive layer disposed on the second plane is changed accordingly.

6. The capacitive force sensing touch panel of claim 1, wherein when the first conductive layer and the second conductive layer are driven to be the touch sensing electrode, the first conductive layer and the second conductive layer comprise at least one driving electrode and at least one sensing electrode respectively, the at least one driving electrode and the at least one sensing electrode receive a driving signal and a sensing signal respectively.

7. The capacitive force sensing touch panel of claim 1, wherein when the first conductive layer and the second conductive layer are driven to be the force sensing electrode, the first conductive layer comprises at least one driving electrode receiving a force sensing signal, a driving signal or a reference voltage, the second conductive layer comprises at least one sensing electrode receiving a ground level or a floating level.

8. The capacitive force sensing touch panel of claim 1, wherein when the first conductive layer and the second conductive layer are driven to be the touch sensing electrode, the first conductive layer comprises at least one driving electrode receiving a driving signal, the second conductive layer comprises at least one sensing electrode receiving a sensing signal and at least one dummy electrode receiving a floating level, the at least one sensing electrode and the at least one dummy electrode are spaced from each other.

9. The capacitive force sensing touch panel of claim 1, wherein when the first conductive layer and the second conductive layer are driven to be the force sensing electrode, the first conductive layer comprises at least one driving electrode receiving a force sensing signal, a driving signal or a reference voltage, the second conductive layer comprises at least one sensing electrode and at least one dummy electrode, the at least one sensing electrode and the at least one dummy electrode are spaced from each other and both receive a ground level or a floating level.

10. The capacitive force sensing touch panel of claim 1, wherein the first substrate and the second substrate are formed by a transparent material.

11. The capacitive force sensing touch panel of claim 1, wherein the laminated structure further comprises a cover lens, the cover lens is formed by a transparent material and disposed above the second substrate, the first conductive layer and the second conductive layer.

12. The capacitive force sensing touch panel of claim 1, wherein the second substrate is formed by an elastic material which can be compressed and deformed by force, the first conductive layer and the second conductive layer are disposed on a lower surface and an upper surface of the second substrate respectively.

13. The capacitive force sensing touch panel of claim 1, wherein a force sensing mode of the capacitive force sensing touch panel and a display mode of the capacitive force sensing touch panel are driven in a time-sharing way, the capacitive force sensing touch panel is operated in the force sensing mode during a blanking interval of a display period to drive the first conductive layer and the second conductive layer to be the force sensing electrode; the capacitive force sensing touch panel is operated in the display mode and the force sensing mode simultaneously during a display interval of the display period.

14. The capacitive force sensing touch panel of claim 1, wherein a touch sensing mode and force sensing mode of the capacitive force sensing touch panel and a display mode of the capacitive force sensing touch panel are driven in a time-sharing way, the capacitive force sensing touch panel is operated in the touch sensing mode and the force sensing mode respectively during a blanking interval of a display period to drive the first conductive layer and the second conductive layer to be the touch sensing electrode and the force sensing electrode respectively.

15. The capacitive force sensing touch panel of claim 14, wherein the blanking interval comprises at least one of a vertical blanking interval (VBI), a horizontal blanking interval (HBI), and a long horizontal blanking interval, the long horizontal blanking interval has a time length equal to or larger than that of the horizontal blanking interval, the long horizontal blanking interval is obtained by redistributing a plurality of the horizontal blanking interval or the long horizontal blanking interval comprises the vertical blanking interval.

16. The capacitive force sensing touch panel of claim 1, wherein the second substrate is an encapsulation layer, the second conductive layer is disposed above the first conductive layer, the laminated structure further comprises an elastic layer disposed between the cathode layer and the first conductive layer, when the elastic layer is compressed and deformed by force, a distance between the first conductive layer disposed above the elastic layer and the cathode layer disposed under the elastic layer is changed accordingly, but a distance between the first conductive layer and the second conductive layer is not changed.

17. The capacitive force sensing touch panel of claim 16, wherein the first conductive layer is driven to be force sensing electrodes and the second conductive layer is driven to be touch sensing electrodes.

18. The capacitive force sensing touch panel of claim 16, wherein when a force is provided to the laminated structure, the second conductive layer is used to shield the first conductive layer.

19. The capacitive force sensing touch panel of claim 16, wherein the elastic layer is formed by at least one compressible spacer.

20. The capacitive force sensing touch panel of claim 17, wherein there is a specific proportion between a number of the force sensing electrodes formed by the first conductive layer and a number of the touch sensing electrodes formed by the second conductive layer.

21. The capacitive force sensing touch panel of claim 17, wherein conducting pads are disposed on the first conductive layer driven to be the force sensing electrodes and the second conductive layer driven to be the touch sensing electrodes respectively and the conducting pads are electrically connected with conduct bars to transmit force sensing signals and touch sensing signals respectively.

22. The capacitive force sensing touch panel of claim 17, wherein the first conductive layer driven to be the force sensing electrodes is formed by transparent conductive material, and the first conductive layer is divided into blocks partially overlapping a display area of the OLED layer.

23. The capacitive force sensing touch panel of claim 17, wherein the first conductive layer driven to be the force sensing electrodes is formed by conductive material and disposed above the OLED layer in mesh type without overlapping a display area of the OLED layer.

24. The capacitive force sensing touch panel of claim 16, wherein the first conductive layer and the second conductive layer are disposed on a lower surface and an upper surface of the second substrate respectively.

25. The capacitive force sensing touch panel of claim 16, wherein the second conductive layer is disposed on a lower surface of the second substrate and the first conductive layer is disposed between the second conductive layer and the cathode layer.

26. The capacitive force sensing touch panel of claim 1, wherein when the capacitive force sensing touch panel is operated in a touch sensing mode, the capacitive force sensing touch panel drives the second conductive layer to be touch sensing electrodes and maintains the first conductive layer at a fixed voltage to pretend touch sensing of the touch sensing electrodes from noise interference.

27. The capacitive force sensing touch panel of claim 1, wherein when the capacitive force sensing touch panel is operated in a force sensing mode, the capacitive force sensing touch panel drives the first conductive layer to be force sensing electrodes and maintains the second conductive layer at a fixed voltage to pretend force sensing of the force sensing electrodes from noise interference and to shield the force sensing electrodes.

28. The capacitive force sensing touch panel of claim 1, wherein the capacitive force sensing touch panel drives the first conductive layer and the second conductive layer to be force sensing electrodes and touch sensing electrodes respectively with the same amplitude, the same phase or the same frequency to reduce driving loading without decreasing a force sensing time and a touch sensing time.

29. The capacitive force sensing touch panel of claim 1, wherein a touch sensing period and a display interval of the capacitive force sensing touch panel are at least partially overlapped; during the touch sensing period, the capacitive force sensing touch panel drives the second conductive layer to be touch sensing electrodes and maintains the first conductive layer at a fixed voltage.

30. The capacitive force sensing touch panel of claim 1, wherein a force sensing period and a display interval of the capacitive force sensing touch panel are at least partially overlapped.

31. A capacitive force sensing touch panel, comprising:
a plurality of pixels, a laminated structure of each pixel comprising:
a first substrate;
an anode layer disposed above the first substrate;
an organic light-emitting diode (OLED) layer disposed above the anode layer;
a cathode layer disposed above the OLED layer;
a second substrate disposed above the cathode layer; and
a conductive layer disposed under the OLED layer and driven to be a force sensing electrode.

32. The capacitive force sensing touch panel of claim 31, wherein the capacitive force sensing touch panel has an out-cell touch panel structure, an on-cell touch panel structure or an in-cell touch panel structure.

33. The capacitive force sensing touch panel of claim 31, wherein the conductive layer forms a single-layer self-capacitive structure or a single-layer mutual-capacitive structure.

34. The capacitive force sensing touch panel of claim 31, wherein the conductive layer is formed by transparent material or opaque material.

35. The capacitive force sensing touch panel of claim 31, further comprises an elastic layer disposed between the cathode layer and the conductive layer, when the elastic layer is compressed and deformed by force, a distance between the conductive layer and the cathode layer is changed accordingly.

36. The capacitive force sensing touch panel of claim 35, wherein the elastic layer is replaced by an air.

37. The capacitive force sensing touch panel of claim 31, wherein the conductive layer is disposed on a lower surface of the first substrate.

38. The capacitive force sensing touch panel of claim 31, wherein the first substrate is formed by an elastic material which can be compressed and deformed by force.

39. The capacitive force sensing touch panel of claim 31, further comprising a third substrate disposed under the first substrate, and the conductive layer is disposed on an upper surface of the third substrate.

40. The capacitive force sensing touch panel of claim 39, further comprises an elastic layer disposed between the first substrate and the third substrate, when the elastic layer is compressed and deformed by force, a distance between the cathode layer and the conductive layer is changed accordingly.

41. The capacitive force sensing touch panel of claim 40, wherein the elastic layer is replaced by an air.

42. The capacitive force sensing touch panel of claim 31, wherein a force sensing mode of the capacitive force sensing touch panel and a touch sensing mode or a display mode of the capacitive force sensing touch panel are driven in a time-sharing way.

43. The capacitive force sensing touch panel of claim 31, wherein a force sensing mode of the capacitive force sensing touch panel and a touch sensing mode or a display mode of the capacitive force sensing touch panel are driven simultaneously.

44. The capacitive force sensing touch panel of claim 31, further comprising a shielding electrode disposed above the conductive layer, when the conductive layer is driven to be force sensing electrodes, the shielding electrode is a reference electrode or a ground electrode.
